(19) United States
(12) Patent Application Publication
(10) Pub. No.: US 2025/0132747 A1
(43) Pub. Date: Apr. 24, 2025

(54) MEMS SWITCH, DRIVING METHOD THEREOF, AND ELECTRONIC DEVICE

(71) Applicants: Beijing BOE Technology Development Co., Ltd., Beijing (CN); BOE Technology Group Co., Ltd., Beijing (CN)

(72) Inventors: Yingli SHI, Beijing (CN); Yanzhao LI, Beijing (CN)

(21) Appl. No.: 18/689,219

(22) PCT Filed: Jan. 17, 2023
(86) PCT No.: PCT/CN2023/072585

§ 371 Date: Mar. 5, 2024

(51) Int. Cl. H03H 9/125; B81B 3/00; H03H 9/24

(52) U.S. Cl. CPC H03H 9/125; B81B 3/0021; H03H 9/2447; B81B 2201/018

(57) ABSTRACT

A MEMS switch includes: a substrate, an anchor point, the first signal line, a first driving electrode, a switch beam, and a second signal line. The anchor point is on the substrate. The first signal line and the first driving electrode are on the substrate, and are arranged on two sides of the anchor point. The second signal line is on a side of the anchor point close to the substrate. The switch beam is connected with the anchor point, and two ends of the switch beam are suspended and on the side of the anchor point away from the substrate, an orthographic projection of the switch beam onto the substrate surface coincides at least partially with the orthographic projection of the first signal line onto the substrate surface, and an orthographic projection of the first driving electrode onto the substrate surface, respectively.

### TECHNICAL FIELD

The present disclosure relates to the technical field of semiconductors, and in particular, to a MEMS switch, a driving method thereof, and an electronic device.

### BACKGROUND

Radio Frequency-Micro-Electro-Mechanical Systems (RF-MEMS) are RF products processed with MEMS technology. RF-MEMS technology is expected to achieve high integration with MMIC (Monopthic Microwave Integrated Circuit), making it possible to create system-on-chip (SOC) that integrates information collection, processing, transmission, processing and execution. RF-MEMS switches are widely used in electronic devices.

RF-MEMS switches may be divided into fixed beam structures and cantilever beam structures according to their structures, and may be divided into electrostatic drive, electromagnetic drive, electrothermal drive, and piezoelectric drive according to their driving methods. The electrostatic driving method is relatively mature in technology, which is the most widely researched, and is currently the most widely used driving mechanism. Compared with traditional switches, RF-MEMS switches have advantages such as low loss, low power consumption, good linearity, high isolation, small size, and easy integration, avoiding the ohmic loss and I-V nonlinearity brought by P-N junctions and metal-semiconductor junctions in traditional FET (Field Effect Transistor) and PIN (Positive-Intrinsic-Negative) switches, overcoming the large size and power consumption caused by traditional external discrete components and the parasitic effects caused by component wiring, and may be applied to microwave systems instead of conventional semiconductor devices. However, RF-MEMS switches are easily affected by internal and external factors such as stress, moisture, high temperature and pressure, and the structural characteristics of the component itself. The switch is prone to “adhesion” failure during operation, resulting in the switch being unable to rebound and having low reliability defects, which in turn leads to relatively high device damage costs.

### SUMMARY

The present disclosure provides a MEMS switch, a driving method thereof, and an electronic device.

The first aspect of embodiments of the present disclosure provides a MEMS switch. The MEMS switch includes: a substrate, an anchor point, a first signal line, a first driving electrode, a switch beam, and a second signal line. The anchor point is on a side of the substrate. The first signal line and the first driving electrode are on the side of the substrate on which the anchor point is located, where the first signal line and the first driving electrode are respectively arranged on two sides of the anchor point along a first direction, the first direction is parallel to a substrate surface of the substrate. A distance between a side of the anchor point away from the substrate surface and the substrate surface is greater than a distance between a side of the first signal line away from the substrate surface and the substrate surface, and greater than a distance between a side of the first driving electrode away from the substrate surface and the substrate surface, respectively. The second signal line is on a side of the anchor point close to the substrate. The switch beam is connected with the anchor point, two ends of the switch beam are suspended and on the side of the anchor point away from the substrate, an orthographic projection of the switch beam onto the substrate surface coincides at least partially with an orthographic projection of the first signal line onto the substrate surface, and an orthographic projection of the first driving electrode onto the substrate surface, respectively.

In an embodiment, the switch beam includes a plurality of switch beam segments with the anchor point as a dividing point. The switch beam segments correspond to the first signal line and first driving electrode respectively.

When a distance between a switch beam segment on a side of the anchor point and the corresponding first signal line decreases, a distance between a switch beam segment on the other side of the anchor point and the corresponding first driving electrode increases. When the distance between the switch beam segment on a side of the anchor point and the corresponding first signal line increases, the distance between the switch beam segment on the other side of the anchor point and the corresponding first driving electrode decreases.

In an embodiment, the MEMS switch further includes a first insulation layer on a side of the first driving electrode away from the substrate surface.

A distance between a side of the first insulation layer away from the substrate surface and the substrate surface is less than the distance between a side of the anchor point away from the substrate surface and the substrate surface.

In an embodiment, the MEMS switch further includes a dielectric layer on a side of the first signal line away from the substrate surface.

A distance between a side of the dielectric layer away from the substrate surface and the substrate surface is less than the distance between a side of the anchor point away from the substrate surface and the substrate surface.

In an embodiment, the MEMS switch further includes a second driving electrode on the substrate surface and between the first signal line and the second signal line adjacent to the first signal line.

A distance between a side of the second driving electrode away from the substrate surface and the substrate surface is less than the distance between the side of the anchor point away from the substrate surface and the substrate surface.

In an embodiment, adjacent switch beam segments correspond to the first driving electrode and second driving electrode respectively.

When a distance between a switch beam segment on a side of the anchor point and the corresponding first driving electrode decreases, a distance between a switch beam segment on the other side of the anchor point and the corresponding second driving electrode increases. When the distance between the switch beam segment on a side of the anchor point and the corresponding first driving electrode increases, the distance between the switch beam segment on the other side of the anchor point and the corresponding second driving electrode decreases.

In an embodiment, the MEMS switch further includes a second insulation layer on a side of the second driving electrode away from the substrate surface.

A distance between a side of the second insulation layer away from the substrate surface and the substrate surface is less than the distance between a side of the anchor point away from the substrate surface and the substrate surface.

In an embodiment, the switch beam segments include a plurality of first switch branch beams between the second signal line and the first driving electrode adjacent to the second signal line.

The first driving electrode includes a plurality of first driving sub-electrodes, and the plurality of first driving sub-electrodes respectively correspond to the plurality of first switch branch beams, an orthographic projection of the first switch branch beam onto the substrate surface coincides at least partially with an orthographic projection of a corresponding first driving sub-electrode of the plurality of first driving sub-electrodes onto the substrate surface.

In an embodiment, the switch beam segments include a plurality of second switch branch beams between the second signal line and the second driving electrode adjacent to the second signal line.

The second driving electrode includes a plurality of second driving sub-electrodes, and the plurality of second driving sub-electrodes respectively correspond to the second switch branch beams, an orthographic projection of the second switch branch beam onto the substrate surface coincides at least partially with an orthographic projection of the second driving sub-electrode onto the substrate surface, and the orthographic projection of the first signal line on the substrate surface, respectively.

The second aspect of embodiments of the present disclosure provides a driving method of a MEMS switch according to the above-mentioned embodiments, and the method includes:

applying a voltage between the first signal line and the switch beam, such that the switch beam is contacted with the first signal line, and the switch is in a closed state; stopping applying the voltage between the first signal line and the switch beam, and applying a voltage between the first driving electrode and the switch beam, such that the switch beam is separated from the first signal line, and the switch is in an off state.

The third aspect of embodiments of the present disclosure provides a driving method of a MEMS switch according to the above-mentioned embodiments, and the method includes:

applying a voltage between the second driving electrode and the switch beam, such that the distance between the switch beam and the second driving electrode decreases, the switch beam is contacted with the first signal line, and the switch is in a closed state; stopping applying the voltage between the first signal line and the switch beam, and applying a voltage between the first driving electrode and the switch beam, such that the distance between the switch beam and the first signal line increases, the switch beam is separated from the first signal line, and the switch is in an off state.

The fourth aspect of embodiments of the present disclosure provides a driving method of a MEMS switch according to the above-mentioned embodiments, and the method includes:

applying a voltage between any one of the switch beam segments and the corresponding first signal line, such that the switch beam segment is contacted with the corresponding first signal line, the switch is in a closed state; stopping applying the voltage between the switch beam segment and the corresponding first signal line, and applying a voltage between any one of the first switch branch beams of another switch beam segment adjacent to the switch beam segment and the corresponding first driving sub-electrode, such that the switch beam segment is separated from the first signal line, the switch is in an off state.

The fifth aspect of embodiments of the present disclosure provides a driving method of a MEMS switch according to the above-mentioned embodiments, and the method includes:
applying a voltage between any one of the second switch branch beams and the corresponding second driving sub-electrode, such that the second switch branch beam is contacted with the corresponding first signal line, the switch is in a closed state; stopping applying the voltage between the second switch branch beam and the corresponding second driving sub-electrode, and applying a voltage between another switch beam segment adjacent to the second switch branch beam and the corresponding first driving sub-electrode, such that the second switch branch beam is separated from the first signal line, the switch is in an off state.

The additional aspects and advantages of present disclosure will be partially provided in the following description, which will become apparent from the following description or can be understood through the practice of present disclosure.

### BRIEF DESCRIPTION OF DRAWINGS

The accompanying drawings, which are incorporated herein and constitute a part of this specification, illustrate embodiments consistent with the present disclosure and, together with this specification, serve to explain the principles of the present disclosure.

FIG. 1 is a structural diagram of a MEMS switch according to an embodiment of the present disclosure;

FIG. 2 is a structural diagram of a MEMS switch according to another embodiment of the present disclosure;

FIG. 3 is a top view of the MEMS switch illustrated in FIG. 2;

FIG. 4 shows a switch in an off state when applying a voltage between the first signal line and the switch beam of the MEMS switch illustrated in FIG. 2;

FIG. 5 is a three-dimensional view of the MEMS switch illustrated in FIG. 4;

FIG. 6 is a static electric field distribution diagram of the MEMS switch when applying a voltage between the first driving electrode and the switch beam of the MEMS switch illustrated in FIG. 2;

FIG. 7 is a finite element simulation experimental diagram of the MEMS switch when applying a voltage between the first driving electrode and the switch beam of the MEMS switch illustrated in FIG. 2;

FIG. 8 is a configuration comparison side view before and after applying a voltage between the first driving electrode and the switch beam of the MEMS switch illustrated in FIG. 2;

FIG. 9 is a structural diagram of a MEMS switch according to another embodiment of the present disclosure;

FIG. 10 is a top view of the MEMS switch illustrated in FIG. 8;

FIG. 11 is a structural diagram of a MEMS switch according to another embodiment of the present disclosure;

FIG. 12 is a top view of the MEMS switch illustrated in FIG. 11;

FIG. 13 is a structural diagram of a MEMS switch according to another embodiment of the present disclosure;

FIG. 14 is a top view of the MEMS switch illustrated in FIG. 13;

FIG. 15 is a structural diagram of a MEMS switch according to another embodiment of the present disclosure;

FIG. 16 is a side view of the MEMS switch A-A′ section illustrated in FIG. 15;

FIG. 17 is a side view of the MEMS switch B-B′ section illustrated in FIG. 16; and

FIG. 18 is a MEMS single-pole multi-throw switch or a MEMS switch array based on the MEMS switch provided by the present disclosure.

In the drawings:
1-substrate; 2-anchor point; 3-first signal line; 4-first driving electrode; 41-first driving sub-electrode; 5-switch beam; 51-first switch branch beam; 6-first insulation layer; 7-second signal line; 8-dielectric layer; 9-second driving electrode; 10-second insulation layer; 100-MEMS switch.

### DETAILED DESCRIPTION

Embodiments will be described in detail here, examples of which are illustrated in the accompanying drawings. When the following description relates to the accompanying drawings, unless specified otherwise, the same numerals in different drawings represent the same or similar elements. The implementations described in the following exemplary embodiments do not represent all implementations consistent with the present disclosure. Conversely, they are merely examples of apparatuses and methods consistent with some aspects of the present disclosure as detailed in the appended claims.

The terms used in this application are merely for the purpose of describing specific embodiments, and are not intended to limit this application. The terms “a”, “said” and “the” of singular forms used in this application and the appended claims are also intended to include plural forms, unless the context clearly indicates otherwise. It should also be understood that, the term “and/or” used herein indicates and includes any or all possible combinations of one or more associated listed items.

The development idea of the present disclosure includes: traditional electrostatic-driven RF-MEMS switches include a substrate and a metal beam on the substrate, a signal line below the metal beam, and a ground wire connected with the metal beam. The application of RF-MEMS switches in circuits can be divided into resistive-contact series switches with metal-metal contact and capacitively coupled parallel switches with metal-insulation-metal contact. The working principle of the resistive-contact series switch is to apply a DC bias voltage between the metal beam and the signal line, the DC bias voltage generates a electrostatic force between the metal beam and the signal line, causing the metal beam to bend and eventually be in contact with the signal line, the signal passes through the metal beam to form a microwave path between the ground wire and the signal line, and the contact electrode conducts the signal line in series, such that the switch is closed. Conversely, when the bias voltage is removed, the metal beam returns to its initial position due to its own elastic restoring force and is separated from the signal line, and the microwave path is disconnected, such that the switch is off. The capacitively coupled parallel switch has a dielectric layer on a side of the signal line close to the metal beam to achieve insulation and block the electrical signal. The working principle of the capacitively coupled parallel switch is to apply a DC bias voltage between the metal beam and the signal line, the DC bias voltage generates an electrostatic force between the metal beam and the signal line, causing the metal beam to bend and eventually be in contact with the dielectric layer on the signal line. Since the large initial distance between the metal beam and the signal line and the capacitance is small, the RF signal is passed along the signal line, but as the distance between the metal beam and the signal line decreases, the capacitance will increase, then the RF signal will be coupled to the ground wire through the metal beam, such that the switch is closed. Conversely, when the bias voltage is removed, the metal beam returns to its initial position due to its own elastic restoring force, the distance between the metal beam and the signal line increases, and the capacitance decreases, so the RF signal will not be coupled to the ground wire but will continue to be passed along the signal line, such that the switch is off.

However, in the resistive-contact series switch, repeated collisions between the metal beam and the signal line can cause pitting and hardening of the metal beam, which reduces the actual contact area between the metal beam and the signal line, lowering the reliability of the switch. The design of the capacitively coupled parallel switches avoids the problem of point contact degradation in DC voltage switches, but due to the easy formation of charge accumulation in the switch dielectric layer, generating electrostatic attraction, the metal beam is prone to “adhesion” failure with the signal line, lowering the reliability of the switch.

A MEMS switch 100, a driving method thereof, and an electronic device are provided by the present disclosure to solve the above technical problems of related technology.

Embodiments of the present disclosure provides a MEMS switch, a driving method thereof, and an electronic device. The following, in conjunction with the accompanying drawings, provides a detailed explanation of the MEMS switch 100, a driving method thereof and an electronic device in the embodiments of the present disclosure. If there is no conflict, features in the embodiments described below may complement each other or be combined with each other.

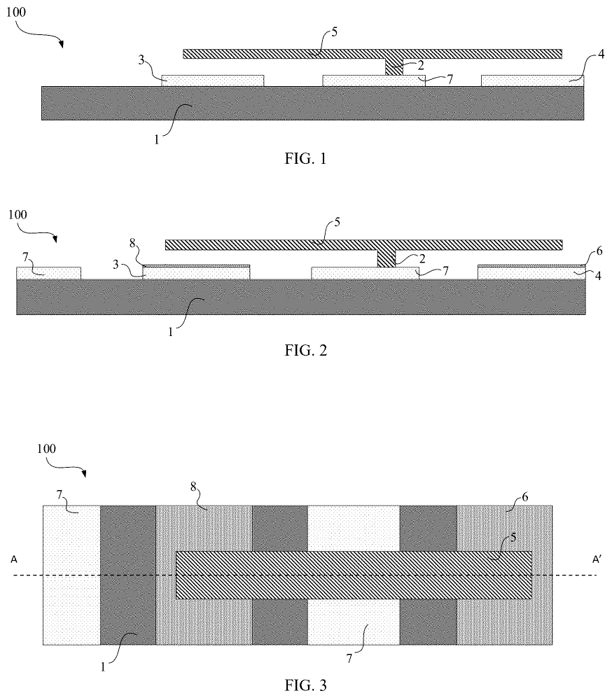

The embodiments of the present disclosure provide a MEMS switch 100, as shown in FIG. 1, the MEMS switch 100 includes: a substrate 1, an anchor point 2, a first signal line 3, a first driving electrode 4, a switch beam 5, and a second signal line 7. The anchor point 2 is on a side of the substrate 1. The first signal line 3 and the first driving electrode 4 are on the side of the substrate 1 on which the anchor point 2 is located, and are respectively arranged on two sides of the anchor point 2 along a first direction, the first direction is parallel to a substrate surface of the substrate 1; the distance between a side of the anchor point 2 away from the substrate surface and the substrate surface is greater than the distance between a side of the first signal line 3 away from the substrate surface and the substrate surface, and greater than the distance between a side of the first driving electrode 4 away from the substrate surface and the substrate surface, respectively. The second signal line 7 is on a side of the anchor point 2 close to the substrate 1. The switch beam 5 is connected with the anchor point 2, and two ends of the switch beam 5 are suspended and on the side of the anchor point 2 away from the substrate 1, the orthographic projection of the switch beam 5 onto the substrate surface coincides at least partially with the orthographic projection of the first signal line 3 onto the substrate surface, and the orthographic projection of the first driving electrode 4 onto the substrate surface, respectively.

In the embodiments of the present disclosure, the first driving electrode 4 is added in the electrostatic-driven MEMS switch 100 as an auxiliary electrode to assist the switch beam 5 to achieve rebound, which is on the side of the anchor point 2 away from the first signal line 3, where the anchor point 2 connects between the switch beam 5 and the substrate 1. When a driving voltage is applied between the switch beam 5 and the first signal line 3, the electrostatic force generated between the switch beam 5 and the first signal line 3 causes the switch beam 5 to contact the first signal line 3. When there is connection between the switch beam 5 and the first signal line 3 due to environmental factors and structural characteristics, resulting in an inability to rebound normally, a DC bias driving voltage is applied between the first driving electrode 4 and the switch beam 5, reducing the distance between the switch beam 5 and the first driving electrode 4, and increasing the distance between the switch beam 5 and the first signal line 3, thus allowing the switch to freely switch between “closed” and “off” states. This improves the reliability of the MEMS switch 100, extends the service life of the switch, and enhances product performance.

Meanwhile, the traditional MEMS switch 100 relies on the structural characteristics of the switch beam 5 to rebound, which requires a certain rebound time. In the embodiment of the present disclosure, the first driving electrode 4 is added, which can shorten the response time of the MEMS switch 100 by rebounding under the action of electrostatic force, thereby improving the overall performance of the switch.

In an example, as shown in FIG. 1, the first signal line 3 and the second signal line 7 in the MEMS switch are both microstrip lines, and when the MEMS switch 100 has one anchor point 2, the anchor point 2 is connected with the second signal line 7.

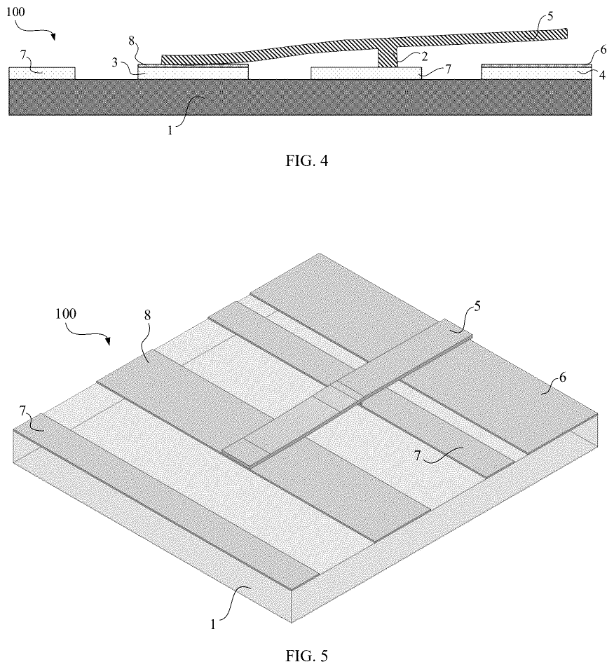

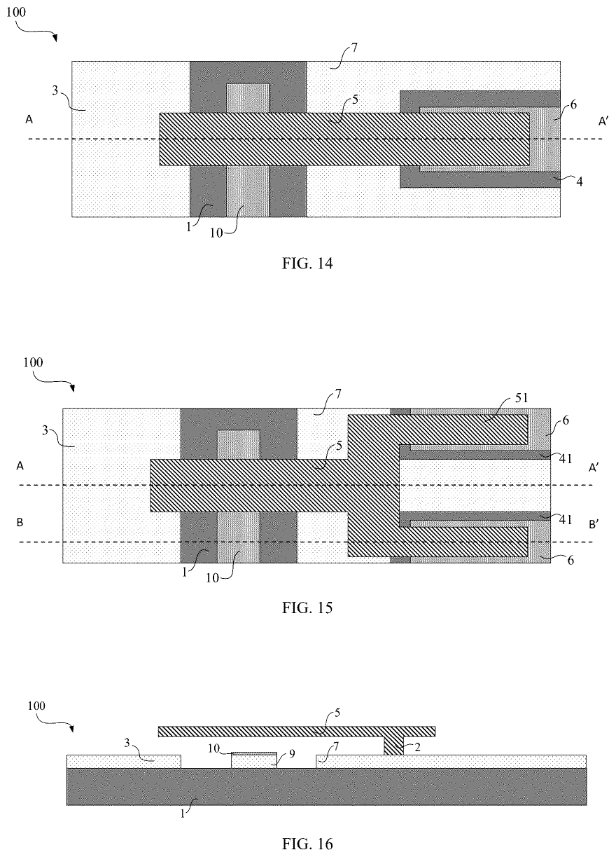

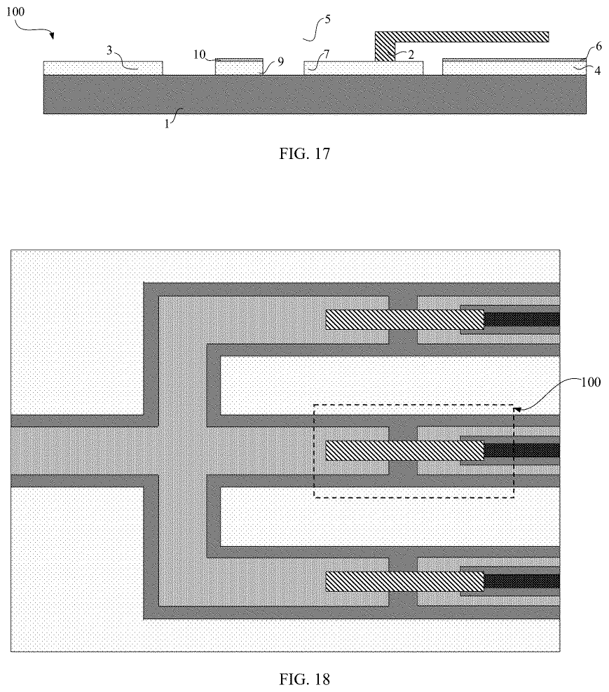

In an example, as shown in FIG. 2 to FIG. 18, the second signal line 7 in the MEMS switch may be a ground wire, on two sides of the first signal line 3 respectively, and form a coplanar waveguide line (CPW) with the first signal 3. Compared to microstrip lines, the coplanar waveguide line (CPW) has the advantages of easy integration and low loss. When the MEMS switch 100 has one anchor point 2, the anchor point 2 is connected with any one of the two second signal lines 7; when the MEMS switch 100 has two anchor points 2, the two second signal lines 7 are respectively connected with the two anchor points 2.

It should be noted that, the substrate 1 in the embodiment may be a rigid substrate, such as silicon-based or glass-based; the substrate 1 may also be a bendable flexible substrate, such as liquid crystal polymer (LCP), polyimide (PI), or Cyclo Olefin Polymer (COP). The materials for the switch beam 5, the anchor point 2, the first signal line 3, and the second signal line 7 are all metals, which may be aluminum, copper, silver, gold, or nickel, as long as they may conduct current. Those skilled in the art can make a selection based on actual design requirements, and the present disclosure does not impose any particular restrictions.

In some embodiments, the materials of the switch beam 5 and the anchor point 2 are the same, and the switch beam 5 and the anchor point 2 are formed as an integral structure, which may improve the mechanical structural stability of the switch beam 5.

In some embodiments, a number of anchor points 2 is n, where n is a positive integer greater than zero. Generally, the longer the length of the switch beam 5 is, the more anchor points 2 are, to avoid contact between one end of the switch beam 5 and the first signal line 3 when the driving voltage is not applied. Those skilled in the art can make a selection based on actual design requirements, and the present disclosure does not impose any particular restrictions.

In some embodiments, as shown in FIG. 1 to FIG. 10, the MEMS switch 100 is provided with one anchor point 2, and the switch beam 5 is a T-shaped cantilever beam in the relevant technology. The first signal line 3 and the first driving electrode 4 are respectively on two sides of the anchor point 2 to control the motion state of the switch beam 5.

In an example, when the MEMS switch 100 is provided with one anchor point 2, the anchor point 2 is at half of the total length of the switch beam 5, i.e., the midpoint of the switch beam 5, then by balancing the voltage applied between the switch beam 5 and the first signal line 3 with the voltage applied between the switch beam 5 and the first driving electrode 4 the movement trend of the switch beam 5 can be controlled.

In an example, when the MEMS switch 100 is provided with one anchor point 2, the anchor point 2 is at two-thirds of the total length of the switch beam 5, the first signal line 3 and the first driving electrode 4 respectively correspond to the two ends of the switch beam 5, and a distance between the anchor point 2 and the first signal line 3 is less than a distance between the anchor point 2 and the first driving electrode 4. At this time, when the switch beam 5 is stuck and needs to rebound, the voltage applied to the first driving electrode 4 is less than the voltage applied between the switch beam 5 and the first signal line 3, which can control the movement trend of the switch beam 5.

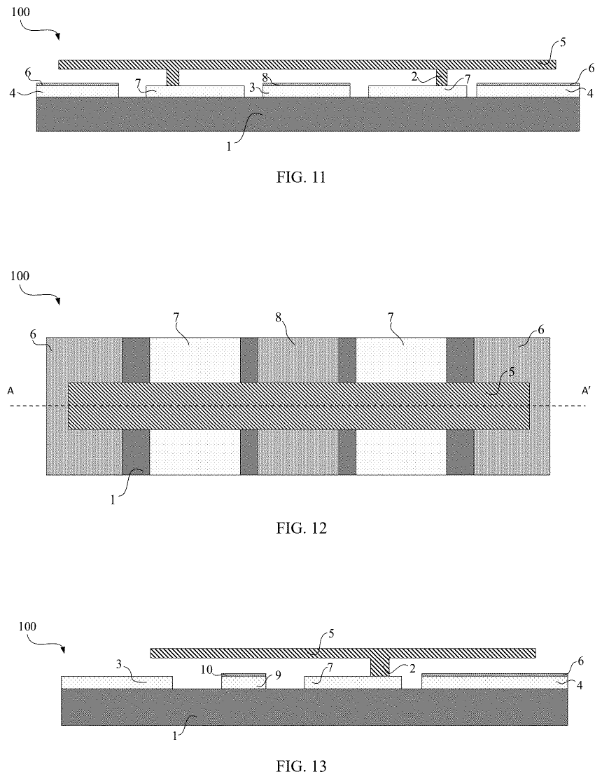

In some embodiments, as shown in FIG. 11 to FIG. 12, the MEMS switch 100 has two anchor points 2, and the switch beam 5 is a double-clamped beam in the relevant technology. At this time, the first signal line 3 is between the two anchor points 2, compared to the scheme of providing only one anchor point 2, the two anchor points 2 may more stably support the switch beam 5, which may enhance the reliability and mechanical stability of the switch to a certain extent.

In an example, the MEMS switch 100 is provided with a first anchor point 2 and a second anchor point 2, the first signal line 3 is between the first anchor point 2 and the second anchor point 2, the first driving electrode 4 is on a side of the first anchor point 2 away from the first signal line 3, to generate a certain rebound electrostatic force.

In an example, the MEMS switch 100 is provided with the first anchor point 2 and the second anchor point 2, the first signal line 3 is between the first anchor point 2 and the second anchor point 2, the first driving electrode 4 is on a side of the second anchor point 2 away from the first signal line 3, to generate a certain rebound electrostatic force.

In an example, the MEMS switch 100 is provided with the first anchor point 2 and the second anchor point 2, there are two first driving electrodes 4, which are respectively on a side of the first anchor point 2 away from the first signal line 3 and a side of the second anchor point 2 away from the first signal line 3, both acting on two sides to produce a better rebound effect.

It should be noted that, the number of the first driving electrode 4 is n, where n is a positive integer greater than zero. When the distances between the two ends of the switch beam 5 and the anchor point 2 are relatively long, a plurality of driving electrodes may be provided to achieve the control of the switch beam 5. Those skilled in the art can make a selection based on actual design requirements, and the present disclosure does not impose any particular restrictions.

In some embodiments, the switch beam 5 includes a plurality of switch beam segments with the anchor point 2 as a dividing point; the switch beam segments correspond to the first signal line 3 or first driving electrode 4 respectively; when the distance between a switch beam segment on a side of the anchor point 2 and the corresponding first signal line 3 decreases, the distance between a switch beam segment on the other side of the anchor point 2 and the corresponding first driving electrode 4 increases; when the distance between the switch beam segment on a side of the anchor point 2 and the corresponding first signal line 3 increases, the distance between the switch beam segment on the other side of the anchor point 2 and the corresponding first driving electrode 4 decreases.

In the embodiments, by applying voltages between the switch beam 5 and the first signal line 3, between the switch beam 5 and the first driving electrode 4, respectively, the motion trend of a plurality of switch beam segments can be controlled, where the arrangement of the first signal line 3 on the substrate 1 may be associated with the relative position of the anchor point 2 to achieve array arrangement control of a plurality of MEMS switches 100.

In some embodiments, as shown in FIG. 2-FIG. 18, the MEMS switch 100 further includes a first insulation layer 6 on a side of the first driving electrode 4 away from the substrate surface;

a distance between a side of the first insulation layer 6 away from the substrate surface and the substrate surface is less than a distance between a side of the anchor point 2 away from the substrate surface and the substrate surface.

In the embodiments, the first insulation layer 6 covers the first driving electrode 4, the main function of the first insulation layer 6 is to avoid direct contact between the first driving electrode 4 and the switch beam 5, thereby achieving DC isolation between the first driving electrode 4 and the switch beam 5, and the first insulation layer 6 is non-sticky, which may play a role in anti-adhesion and improving isolation. Furthermore, the first insulation layer 6 may be made of smooth materials to reduce friction between the switch beam 5 and the first insulation layer 6, to protect the switch beam 5 to avoid wear of the switch beam 5, and to improve the anti-adhesion effect between the first insulation layer 6 and the switch beam 5.

In some embodiments, an area of the orthographic projection of the first insulation layer 6 onto the substrate 1 is less than or equal to an area of the orthographic projection of the first driving electrode 4 onto the substrate 1. The first insulation layer 6 has a certain thickness, and the thickness is not particularly limited, as long as the first insulation layer 6 can avoid contact between the switch beam 5 and the first driving electrode 4.

In some embodiments, the area of the orthographic projection of the first insulation layer 6 onto the substrate 1 is larger than the area of the orthographic projection of the first driving electrode 4 onto the substrate 1. In this way, the first insulation layer 6 fully covers the first driving electrode 4, ensuring that the switch beam 5 is not in contact with the first driving electrode 4.

It should be noted that, the specific size and shape of the first insulation layer 6 are not specifically defined, as long as the first insulation layer 6 can achieve the electrical insulation function between the switch beam 5 and the first driving electrode 4.

In an embodiment, as shown in FIG. 2 to FIG. 18, the MEMS switch 100 further includes a dielectric layer 8 on a side of the first signal line 3 away from the substrate surface.

The distance between the side of the dielectric layer 8 away from the substrate surface and the substrate surface is less than the distance between the side of the anchor point 2 away from the substrate surface and the substrate surface.

It should be noted that, when the dielectric layer 8 is not provided on the side of the first signal line 3 close to the switch beam 5 in the MEMS switch 100, a resistive-contact series switch with metal-metal contact is formed, as shown in FIG. 13 to FIG. 17. When the dielectric layer 8 is provided on the side of the first signal line 3 close to the switch beam 5 in the MEMS switch 100, a capacitively coupled parallel switch with metal-insulation-metal contact is formed, as shown in FIG. 2 to FIG. 12.

In the embodiment, the dielectric layer 8 is made of insulation materials, which may be silicon nitride or silicon oxynitride, there are no specific limitations in the present disclosure, and those skilled in the art can make selections based on actual design requirements.

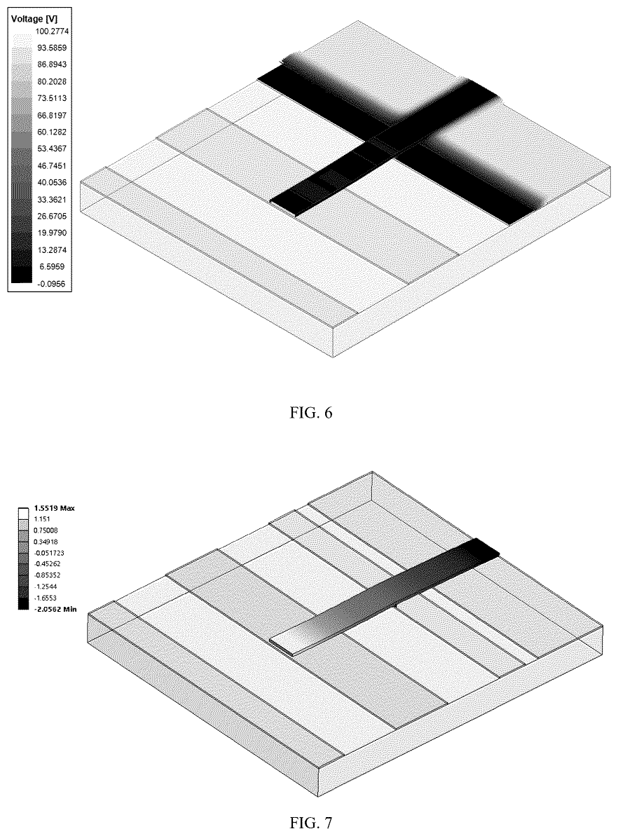

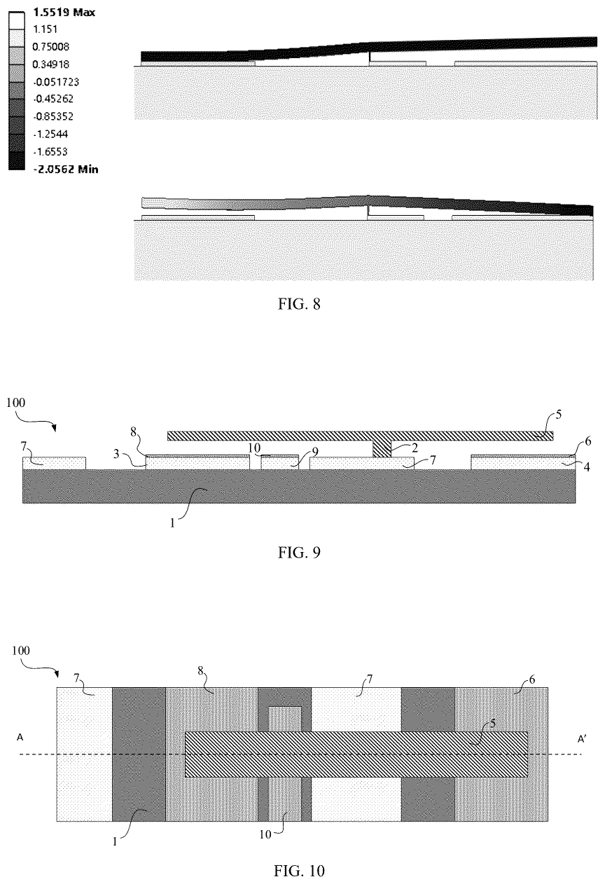

In an example, a finite element simulation experiment is performed on the MEMS switch 100 provided in FIG. 2 to FIG. 5 of the present disclosure, to obtain the corresponding static electric field distribution diagram as shown in FIG. 6. When a voltage is applied between the switch beam 5 and the first driving electrode 4 to separate the switch beam 5 from the first signal line 3, under the action of the electric field, the three-dimensional distribution diagrams of the gap size between the switch beam 5 and the first signal line 3, and the gap size between the switch beam 5 and the first driving electrode 4 are illustrated in FIG. 7. The configuration comparison side view before and after rebound of the switch beam 5 of the MEMS switch 100 under the action of the electric field is illustrated in FIG. 8. Under the action of electrostatic force drive, the switch beam 5 that occurs adhesion failure is separated from the dielectric layer 8, an end of the switch beam 5 close to the first signal line 3 moves 1.55 μm in the direction of the switch beam 5 away from the substrate 1, and an end of the switch beam 5 close to the driving electrode moves 2.06 μm in the direction of the switch beam 5 towards the substrate 1.

In some embodiments, as shown in FIG. 9, the MEMS switch 100 further includes the second driving electrode 9 on the substrate surface and between the first signal line 3 and the second signal line 7 adjacent to the first signal line 3;
the distance between a side of the second driving electrode 9 away from the substrate surface and the substrate surface is less than the distance between the side of the anchor point 2 away from the substrate surface and the substrate surface.

In the embodiment, the second driving electrode 9 is added to the MEMS switch 100, by applying a DC voltage between the second driving electrode 9 and the switch beam 5, the switch beam 5 is driven by the electrostatic force to approach the first signal line 3 and is contacted with the first signal line 3, the signal forms a microwave path along the first signal line 3-metal beam-anchor point 2-second signal line 7, and the switch beam 5 connects the first signal line 3 in series. In the resistive-contact series switch, repeated collisions between the metal beam 5 and the first signal line 3 are easy to cause pitting and hardening of the metal beam 5, so an auxiliary electrode is added to enhance the electrostatic driving force between the switch beam 5 and the first signal line 3, further reducing the gap between the switch beam 5 and the first signal line 3, increasing the actual contact area between the switch beam 5 and the first signal line 3, and improving the reliability of the MEMS switch 100.

In an embodiment, adjacent switch beam segments correspond to the first driving electrode 4 and second driving electrode 9 respectively;
when the distance between a switch beam segment on a side of the anchor point 2 and the corresponding first driving electrode 4 decreases, the distance between a switch beam segment on the other side of the anchor point 2 and the corresponding second driving electrode 9 increases; when the distance between the switch beam segment on a side of the anchor point 2 and the corresponding first driving electrode 4 increases, the distance between the switch beam segment on the other side of the anchor point 2 and the corresponding second driving electrode 9 decreases.

In the embodiment, adjacent switch beam segments correspond to the first driving electrode 4 and second driving electrode 9 respectively; the first driving electrode 4 is configured to prevent the switch beam segment from adhesion to the first signal line 3, and the second driving electrode 9 is configured to assist the switch beam segment to be in contact with the first signal line 3.

In some embodiments, as shown in FIG. 9, the MEMS switch 100 further includes a second insulation layer 10 on the side of the second driving electrode 9 away from the substrate surface;
the distance between a side of the second insulation layer 10 away from the substrate surface and the substrate surface is less than the distance between the side of the anchor point 2 away from the substrate surface and the substrate surface.

In the embodiments, the second insulation layer 10 covers the second driving electrode 9, the main function of the second insulation layer 10 is to avoid direct contact between the second driving electrode 9 and the switch beam 5, achieving DC isolation between the second driving electrode 9 and the switch beam 5, and the second insulation layer 10 is non-sticky, which may play a role in anti-adhesion and improving isolation. Furthermore, the second insulation layer 10 may be made of smooth materials to reduce friction between the switch beam 5 and the second insulation layer 10, to protect the switch beam 5 to avoid wear of the switch beam 5, and to improve the anti-adhesion effect between the second insulation layer 10 and the switch beam 5.

In some embodiments, an area of the orthographic projection of the second insulation layer 10 onto the substrate 1 is less than or equal to an area of the orthographic projection of the second driving electrode 9 onto the substrate 1. The second insulation layer 10 has a certain thickness, and the thickness is not particularly limited, as long as the second insulation layer 10 can avoid contact between the switch beam 5 and the second driving electrode 9.

In some embodiments, the area of the orthographic projection of the second insulation layer 10 onto the substrate 1 is larger than the area of the orthographic projection of the second driving electrode 9 onto the substrate 1. In this way, the second insulation layer 10 fully covers the second driving electrode 9, ensuring that the switch beam 5 is not in contact with the first driving electrode 9.

It should be noted that, the specific size and shape of the second insulation layer 10 are not specifically defined, as long as the second insulation layer 10 can achieve the electrical insulation function between the switch beam 5 and the second driving electrode 9.

In some embodiments, as shown in FIG. 15 to FIG. 17, the switch beam segments include a plurality of first switch branch beams 51 between the second signal line 7 and the first driving electrode 4 adjacent to the second signal line 7;
the first driving electrode 4 includes a plurality of first driving sub-electrodes 41, and the plurality of first driving sub-electrodes 41 respectively correspond to the first switch branch beams 51, an orthographic projection of the first switch branch beam 51 onto the substrate surface coincides at least partially with an orthographic projection of the first driving sub-electrode 41 onto the substrate surface.

In the embodiments, the switch beam 5 is divided into a plurality of first switch beams 51, and the first driving electrode 4 includes a plurality of first driving sub-electrodes 41. Different first switch branch beams 51 correspond to different first driving sub-electrodes 41, if any one of the first driving sub-electrodes 41 fails, the MEMS switch 100 is still provided with other first driving sub-electrodes 41 to control the rebound of the switch beam 5, improving the reliability and fault tolerance of the MEMS switch.

In an embodiment, the switch beam segments include a plurality of second switch branch beams between the second signal line 7 and the second driving electrode 9 adjacent to the second signal line;
the second driving electrode 9 includes a plurality of second driving sub-electrodes, and the plurality of second driving sub-electrodes respectively correspond to the second switch branch beams, an orthographic projection of the second switch branch beam onto the substrate surface coincides at least partially with an orthographic projection of the second driving sub-electrode 9 onto the substrate surface, and the orthographic projection of the first signal line 3 onto the substrate surface, respectively.

The beneficial effects of the embodiment are the same as those of the above-mentioned first switch branch beams 51, and will not be repeated here.

Based on the same inventive concept, the present disclosure provides a driving method of a MEMS switch according to the above-mentioned embodiments, the driving method includes:
applying a voltage between the first signal line 3 and the switch beam 5, such that the switch beam 5 is contacted with the first signal line 3, and the switch is in a closed state; stopping applying the voltage between the first signal line 3 and the switch beam 5, and applying a voltage between the first driving electrode 4 and the switch beam 5, such that the switch beam 5 is separated from the first signal line 3, and the switch is in an off state.

Based on the same inventive concept, the present disclosure provides the second driving method of a MEMS switch according to the above-mentioned embodiments, the driving method includes:
applying a voltage between the second driving electrode 9 and the switch beam 5, such that the distance between the switch beam 5 and the second driving electrode 9 decreases, the switch beam 5 is contacted with the first signal line 3, and the switch is in a closed state; stopping applying the voltage between the first signal line 3 and the switch beam 5, and applying a voltage between the first driving electrode 4 and the switch beam 5, such that the distance between the switch beam 5 and the first signal line 3 increases, the switch beam 5 is separated from the first signal line 3, and the switch is in an off state.

Based on the same inventive concept, the present disclosure provides the third driving method of a MEMS switch according to the above-mentioned embodiments, the driving method includes:
applying a voltage between any one of switch beam segments and the corresponding first signal line 3, such that the switch beam segment is contacted with the corresponding first signal line 3, and the switch is in a closed state; stopping applying the voltage between the switch beam segment and the corresponding first signal line 3, and applying a voltage between any one of the first switch branch beams 51 of another switch beam segment adjacent to the switch beam segment and the corresponding first driving sub-electrode 41, such that the switch beam segment is separated from the first signal line 3, and the switch is in an off state.

Based on the same inventive concept, the present disclosure provides a fourth driving method of a MEMS switch according to the above-mentioned embodiments, the driving method includes:
applying a voltage between any one of second switch branch beams and corresponding second driving sub-electrode, such that the second switch branch beam is contacted with a corresponding first signal line 3, the switch is in a closed state; stopping applying the voltage between the second switch branch beam and the corresponding second driving sub-electrode, and applying a voltage between another switch beam segment adjacent to the second switch branch beam and the corresponding first driving sub-electrode 41, such that the second switch branch beam is separated from the first signal line 3, the switch is in an off state.

The above driving methods can all be implemented, effectively preventing the problem that the switch is unable to rebound due to the MEMS switch 100 is prone to “adhesion” failure during operation, therefore, using these driving methods to control the MEMS switch 100 in the above-mentioned embodiments may improve the reliability of the switch.

Based on the same inventive concept, the present disclosure provides an electronic device. The electronic device includes the above-mentioned MEMS device. Thus, the electronic device has all the features and advantages of the flexible MEMS device mentioned above, and will not be repeated here.

Based on the same inventive concept, as shown in FIG. 18, the present disclosure further provides an RF MEMS single-pole multi-throw switch or RF MEMS switch array based on the MEMS switch 100, where, each MEMS switch 100 is provided with the first driving electrode 4, which may improve the adhesion problem of the switch beam 5 in the single-pole multi-throw switch or the MEMS switch array, and may shorten the response time of the single-pole multi-throw switch or the MEMS switch array. It should be noted that, the present disclosure does not specify the number of output ends of the single-pole multi-throw switch and the number of switch arrays.

The above embodiments of the present disclosure, in the absence of conflicts, may complement each other.

It is to be noted that in the accompanying drawings, the dimensions of layers and regions may be exaggerated for clarity of illustration. It will be understood that when an element or a layer is referred to as being “above” or “on” another element or layer, it may be directly on the other element, or intervening layers may be existed. In addition, it will be understood that when an element or a layer is referred to as being “under” or “below” another element or layer, it may be directly under the other element, or one or more intervening layers or elements may be existed. In addition, it will also be understood that when a layer or an element is referred to as being “between” two layers or two elements, it may be the only layer between the two layers or two elements, or one or more intervening layers or elements may be existed. Like reference numerals indicate like elements throughout.

The terms “center”, “up”, “bottom”, “front”, “back”, “left”, “right”, “vertical”, “horizontal”, “top”, “bottom”, “inside”, “outside”, etc., indicate orientations or positional relationships based on the orientations or positional relationships shown in the drawings and are intended solely for convenience and simplification of the present application, and do not indicate or imply that the device or element referred to must have a particular orientation, be constructed and operated in a particular orientation, and therefore cannot be construed as limiting the present application.

In addition, the terms “first” and “second” are only used for description, and cannot be construed as indicating or implying relative importance or implicitly indicating the number of indicated technical features. Thus, elements limited by “first” and “second” may explicitly or implicitly include one or more features. In the descriptions of the present disclosure, “a plurality” refers to two or more unless otherwise stated clearly.

Those skilled in the art will readily conceive other embodiments of the present disclosure upon consideration of the specification and practice of the various embodiments disclosed herein. This application is intended to cover any variation, use, or adaptive change of this application. These variations, uses, or adaptive changes follow the general principles of this application and include common general knowledge or common technical means in the art that are not disclosed in this application. The specification and the embodiments are considered as merely exemplary, and the real scope and spirit of the present disclosure are pointed out in the following claims.

It should be understood that this application is not limited to the precise structures described above and shown in the accompanying drawings, and various modifications and changes can be made without departing from the scope of this application. The scope of the present disclosure is limited only by the appended claims.

1. A micro electro-mechanical system (MEMS) switch, comprising:
a substrate;
an anchor point, on a side of the substrate;
a first signal line and a first driving electrode, on the side of the substrate on which the anchor point is located, wherein the first signal line and the first driving electrode are respectively arranged on two sides of the anchor point along a first direction, and the first direction is parallel to a substrate surface of the substrate; and a distance between a side of the anchor point away from the substrate surface and the substrate surface is greater than a distance between a side of the first signal line away from the substrate surface and the substrate surface, and greater than a distance between a side of the first driving electrode away from the substrate surface and the substrate surface, respectively;
a second signal line, on a side of the anchor point close to the substrate; and
a switch beam, connected with the anchor point, wherein, two ends of the switch beam are suspended and on the side of the anchor point away from the substrate, an orthographic projection of the switch beam onto the substrate surface coincides at least partially with an orthographic projection of the first signal line onto the substrate surface, and an orthographic projection of the first driving electrode onto the substrate surface, respectively.

2. The MEMS switch according to claim 1, wherein the switch beam comprises a plurality of switch beam segments with the anchor point as a dividing point; the switch beam segments correspond to the first signal line and first driving electrode respectively;
when a distance between a switch beam segment on a side of the anchor point and the corresponding first signal line decreases, a distance between a switch beam segment on the other side of the anchor point and the corresponding first driving electrode increases; and when the distance between the switch beam segment on the side of the anchor point and the corresponding first signal line increases, the distance between the switch beam segment on the other side of the anchor point and the corresponding first driving electrode decreases.

3. The MEMS switch according to claim 2, further comprising a first insulation layer disposed on a side of the first driving electrode away from the substrate surface;
a distance between the side of the first insulation layer away from the substrate surface and the substrate surface is less than the distance between the side of the anchor point away from the substrate surface and the substrate surface.

4. The MEMS switch according to claim 3, further comprising a dielectric layer on the side of the first signal line away from the substrate surface;
a distance between a side of the dielectric layer away from the substrate surface and the substrate surface is less than the distance between the side of the anchor point away from the substrate surface and the substrate surface.

5. The MEMS switch according to claim 4, further comprising a second driving electrode on the substrate surface and between the first signal line and the second signal line adjacent to the first signal line; and
a distance between a side of the second driving electrode away from the substrate surface and the substrate surface is less than the distance between the side of the anchor point away from the substrate surface and the substrate surface.

6. The MEMS switch according to claim 5, wherein adjacent switch beam segments correspond to the first driving electrode and second driving electrode respectively;
when a distance between a switch beam segment on a side of the anchor point and the corresponding first driving electrode decreases, a distance between a switch beam segment on the other side of the anchor point and the corresponding second driving electrode increases; and when the distance between the switch beam segment on the side of the anchor point and the corresponding first driving electrode increases, the distance between the switch beam segment on the other side of the anchor point and the corresponding second driving electrode decreases.

7. The MEMS switch according to claim 6, further comprising a second insulation layer on the side of the second driving electrode away from the substrate surface;
a distance between the side of the second insulation layer away from the substrate surface and the substrate surface is less than the distance between the side of the anchor point away from the substrate surface and the substrate surface.

8. The MEMS switch according to claim 4, wherein the switch beam segments comprise a plurality of first switch branch beams between the second signal line and the first driving electrode adjacent to the second signal line; and
the first driving electrode comprises a plurality of first driving sub-electrodes, and the plurality of first driving sub-electrodes respectively correspond to the plurality of first switch branch beams, an orthographic projection of a first switch branch beam of the plurality of first switch branch beams onto the substrate surface coincides at least partially with an orthographic projection of a corresponding first driving sub-electrode of the plurality of first driving sub-electrodes onto the substrate surface.

9. The MEMS switch according to claim 5, wherein the switch beam segments comprise a plurality of second switch branch beams between the second signal line and the second driving electrode adjacent to the second signal line; and
the second driving electrode comprises a plurality of second driving sub-electrodes, and the plurality of second driving sub-electrodes respectively correspond to the plurality of second switch branch beams, an orthographic projection of a second switch branch beam of the plurality of second switch branch beams onto the substrate surface coincides at least partially with an orthographic projection of a corresponding second driving electrode of the plurality of second driving sub-electrodes onto the substrate surface, and the orthographic projection of the first signal line onto the substrate surface, respectively.

10. A driving method of a MEMS switch, applied to the MEMS switch according to claim 1, wherein the driving method comprises:
applying a voltage between the first signal line and the switch beam, such that the switch beam is contacted with the first signal line, and the switch is in a closed state;
stopping applying the voltage between the first signal line and the switch beam, and
applying a voltage between the first driving electrode and the switch beam, such that the switch beam is separated from the first signal line, and the switch is in an off state.

11. A driving method of a MEMS switch, applied to the MEMS switch according to claim 5, wherein the driving method comprises:
applying a voltage between the second driving electrode and the switch beam, such that the distance between the switch beam and the second driving electrode decreases, the switch beam is contacted with the first signal line, and the switch is in a closed state;
stopping applying the voltage between the first signal line and the switch beam, and
applying a voltage between the first driving electrode and the switch beam, such that the distance between the switch beam and the first signal line increases, the switch beam is separated from the first signal line, and the switch is in an off state.

12. A driving method of a MEMS switch, applied to the MEMS switch according to claim 8, wherein the driving method comprises:
applying a voltage between any one of the switch beam segments and the corresponding first signal line, such that the switch beam segment is contacted with the corresponding first signal line, the switch is in a closed state;
stopping applying the voltage between the switch beam segment and the corresponding first signal line, and
applying a voltage between any one of the first switch branch beams of another switch beam segment adjacent to the switch beam segment and the corresponding first driving sub-electrode, such that the switch beam segment is separated from the first signal line, the switch is in an off state.

13. A driving method of a MEMS switch, applied to the MEMS switch according to claim 9, wherein the driving method comprises:
applying a voltage between any one of the second switch branch beams and the corresponding second driving sub-electrode, such that the second switch branch beam is contacted with the corresponding first signal line, the switch is in a closed state;
stopping applying the voltage between the second switch branch beam and the corresponding second driving sub-electrode, and
applying a voltage between another switch beam segment adjacent to the second switch branch beam and the corresponding first driving sub-electrode, such that the second switch branch beam is separated from the first signal line, the switch is in an off state.

14. An electronic device, comprising the MEMS switch according to claim 1.

15. A driving method of a MEMS switch, applied to the MEMS switch according to claim 2, wherein the driving method comprises:
applying a voltage between the first signal line and the switch beam, such that the switch beam is contacted with the first signal line, and the switch is in a closed state;
stopping applying the voltage between the first signal line and the switch beam, and
applying a voltage between the first driving electrode and the switch beam, such that the switch beam is separated from the first signal line, and the switch is in an off state.

16. A driving method of a MEMS switch, applied to the MEMS switch according to claim 3, wherein the driving method comprises:
applying a voltage between the first signal line and the switch beam, such that the switch beam is contacted with the first signal line, and the switch is in a closed state;
stopping applying the voltage between the first signal line and the switch beam, and
applying a voltage between the first driving electrode and the switch beam, such that the switch beam is separated from the first signal line, and the switch is in an off state.

17. A driving method of a MEMS switch, applied to the MEMS switch according to claim 4, wherein the driving method comprises:
applying a voltage between the first signal line and the switch beam, such that the switch beam is contacted with the first signal line, and the switch is in a closed state;
stopping applying the voltage between the first signal line and the switch beam, and
applying a voltage between the first driving electrode and the switch beam, such that the switch beam is separated from the first signal line, and the switch is in an off state.

18. A driving method of a MEMS switch, applied to the MEMS switch according to claim 6, wherein the driving method comprises:
applying a voltage between the second driving electrode and the switch beam, such that the distance between the switch beam and the second driving electrode decreases, the switch beam is contacted with the first signal line, and the switch is in a closed state;
stopping applying the voltage between the first signal line and the switch beam, and
applying a voltage between the first driving electrode and the switch beam, such that the distance between the switch beam and the first signal line increases, the switch beam is separated from the first signal line, and the switch is in an off state.

19. A driving method of a MEMS switch, applied to the MEMS switch according to claim 7, wherein the driving method comprises:
applying a voltage between the second driving electrode and the switch beam, such that the distance between the switch beam and the second driving electrode decreases, the switch beam is contacted with the first signal line, and the switch is in a closed state;
stopping applying the voltage between the first signal line and the switch beam, and
applying a voltage between the first driving electrode and the switch beam, such that the distance between the switch beam and the first signal line increases, the switch beam is separated from the first signal line, and the switch is in an off state.
